(19) United States
(12) Patent Application Publication
(10) Pub. No.: US 2025/0212488 A1
(43) Pub. Date: Jun. 26, 2025

(54) SEMICONDUCTOR DEVICE

(71) Applicant: Mitsubishi Electric Corporation, Tokyo (JP)

(72) Inventors: Reona FURUKAWA, Tokyo (JP); Shinya SONEDA, Tokyo (JP); Kosuke SAKAGUCHI, Tokyo (JP)

(73) Assignee: Mitsubishi Electric Corporation, Tokyo (JP)

(21) Appl. No.: 18/919,200

(22) Filed: Oct. 17, 2024

(30) Foreign Application Priority Data
Dec. 20, 2023 (JP) 2023-214524

(51) Int. Cl. H01L 29/423; H01L 29/735

(52) U.S. Cl. CPC H10D 64/519; H10D 10/60; H10D 64/518

(57) ABSTRACT

First and second surface electrodes are disposed so as to sandwich finger wiring extending in a first direction. A gate electrode extends in a second direction. A third surface electrode connects the first surface electrode and the second surface electrode between a tip of the finger wiring and gate wiring. A finger wiring extension portion extends from the tip of the finger wiring toward the gate wiring while avoiding the third surface electrode. A gate electrode crossing the third surface electrode in plan view is electrically connected to the finger wiring extension portion.

### BACKGROUND OF THE INVENTION

### Field of the Invention

The present disclosure relates to a semiconductor device.

### Description of the Background Art

In a vertical semiconductor device in which a current flows between a front surface and a back surface of a semiconductor substrate, a linear electrode called a gate liner or a finger electrode for transmitting a gate signal is provided. Such a linear electrode is disposed so as to divide an emitter electrode provided on the front surface of the semiconductor substrate (see, for example, Japanese Patent Application Laid-Open No. 2006-210519).

A gate liner such as the one shown in Japanese Patent Application Laid-Open No. 2006-210519 improves delay of a gate signal. On the other hand, since an emitter electrode is divided by the gate liner, a current distribution becomes unbalanced, and short circuit tolerance is lowered.

### SUMMARY

An object of the present disclosure is to provide a semiconductor device in which short circuit tolerance is improved and delay of a gate signal is lessened.

A semiconductor device according to the present disclosure includes finger wiring, a surface electrode, gate wiring, and a plurality of gate electrodes. The finger wiring extends in a first direction within a plane of a semiconductor substrate. The surface electrode includes a first surface electrode and a second surface electrode arranged so as to sandwich the finger wiring. The gate wiring has an annular shape in plan view and is provided so as to surround the surface electrode. The plurality of gate electrodes extend in a second direction within the plane of the semiconductor substrate. The surface electrode includes a third surface electrode. The third surface electrode is provided on an extension line of the finger wiring. The third surface electrode connects the first surface electrode and the second surface electrode between a tip of the finger wiring and the gate wiring. The finger wiring includes a finger wiring extension portion. The finger wiring extension portion extends from the tip of the finger wiring toward the gate wiring while avoiding the third surface electrode. Among the plurality of gate electrodes, a gate electrode crossing the third surface electrode in plan view is electrically connected to the finger wiring extension portion.

Provided is a semiconductor device in which short circuit tolerance is improved and delay of a gate signal is lessened.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a plan view illustrating a configuration of a semiconductor device according to the first preferred embodiment;

FIG. 2 is an enlarged plan view illustrating the configuration of the semiconductor device;

FIG. 3 is an enlarged plan view illustrating a configuration of a semiconductor device in a first modification of the first preferred embodiment;

FIG. 4 is an enlarged plan view illustrating a configuration of a semiconductor device in a second modification of the first preferred embodiment;

FIG. 5 is an enlarged plan view illustrating a configuration of a semiconductor device in a third modification of the first preferred embodiment;

FIG. 6 is a plan view illustrating a configuration of a semiconductor device according to the second preferred embodiment;

FIG. 7 is a cross-sectional view illustrating a configuration of the semiconductor device;

FIG. 8 is a plan view illustrating a configuration of a semiconductor device according to the third preferred embodiment;

FIG. 9 is a plan view illustrating a configuration of a semiconductor device according to a modification of the third preferred embodiment;

FIG. 10 is a cross-sectional view illustrating a configuration of the semiconductor device;

FIG. 11 is a plan view illustrating a configuration of a semiconductor device according to the fourth preferred embodiment;

FIG. 12 is a cross-sectional view illustrating a configuration of the semiconductor device;

FIG. 13 is a plan view illustrating a configuration of a semiconductor device according to the fifth preferred embodiment;

FIG. 14 is a diagram illustrating a schematic three-dimensional shape of an electrode (AlSi) in an emitter connection region;

FIG. 15 is a plan view illustrating a configuration of a semiconductor device according to the sixth preferred embodiment;

FIG. 16 is a diagram illustrating a configuration of a semiconductor device according to the seventh preferred embodiment;

FIG. 17 is a diagram illustrating a configuration of a semiconductor device according to the seventh preferred embodiment; and

FIG. 18 is a diagram illustrating a configuration of a semiconductor device according to the eighth preferred embodiment.

### DESCRIPTION OF THE PREFERRED EMBODIMENTS

### First Preferred Embodiment

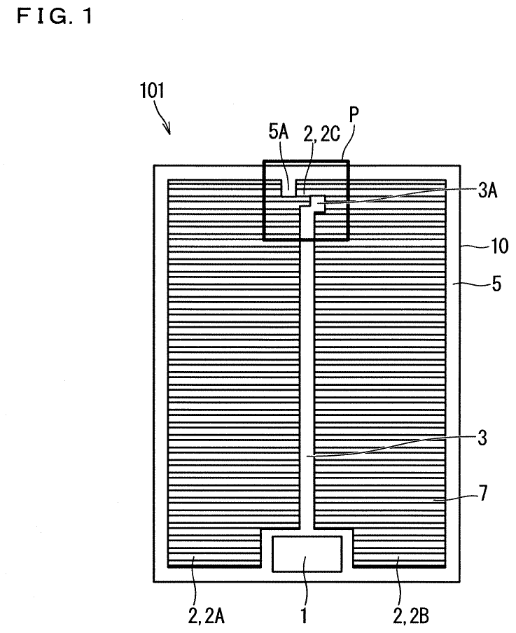

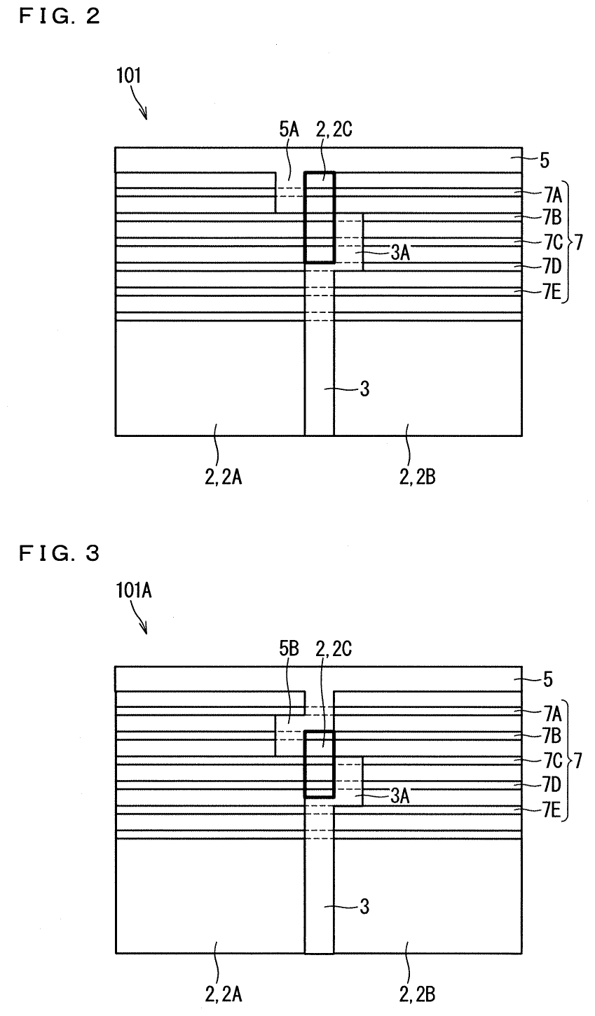

FIG. 1 is a plan view illustrating a configuration of a semiconductor device 101 according to the first preferred embodiment. FIG. 2 is an enlarged plan view illustrating the configuration of the semiconductor device 101. FIG. 2 illustrates a configuration in a region P illustrated in FIG. 1. Note that FIGS. 1 and 2 are illustrative and thus do not completely match. FIGS. 1 and 2 illustrate an upper surface of the semiconductor device 101, and the semiconductor device 101 is a vertical semiconductor device that controls a current flowing between an upper surface and a lower surface of a semiconductor substrate 10.

The semiconductor device 101 includes an active portion (not illustrated), a gate pad 1, an emitter electrode 2, finger wiring 3, a finger wiring extension portion 3A, gate wiring 5, a gate wiring extension portion 5A, and a plurality of gate electrodes 7.

The active portion is provided on the semiconductor substrate 10 (see FIG. 7) and is disposed inside an outer peripheral portion of the semiconductor substrate 10. The active portion includes a semiconductor element (not illustrated). The semiconductor element is formed of, for example, a semiconductor such as Si. The semiconductor is preferably a so-called wide bandgap semiconductor such as SiC, GaN, Ga₂O₃, GeO₂, or diamond. The semiconductor element is a power semiconductor element, a control integrated circuit (IC) for controlling the power semiconductor element, or the like. The semiconductor element is, for example, an insulated gate bipolar transistor (IGBT), a metal oxide semiconductor field effect transistor (MOSFET), a Schottky barrier diode, or the like. Alternatively, the semiconductor element may be a reverse-conducting IGBT (RC-IGBT) in which an IGBT and a freewheeling diode are formed within one semiconductor substrate 10. The semiconductor element in the first preferred embodiment is an IGBT.

The gate pad 1 is provided on the upper surface of the semiconductor substrate 10. The gate pad 1 has a function as a terminal to which a gate signal is input from an outside of the semiconductor device 101.

The emitter electrode 2 is a surface electrode provided in the active portion. The emitter electrode 2 includes a first emitter electrode 2A, a second emitter electrode 2B, and a third emitter electrode 2C. The first emitter electrode 2A corresponds to a first surface electrode. The second emitter electrode 2B corresponds to a second surface electrode. The third emitter electrode 2C corresponds to a third surface electrode.

The first emitter electrode 2A and the second emitter electrode 2B are disposed so as to sandwich the finger wiring 3. In other words, the first emitter electrode 2A is disposed on one side of the finger wiring 3, and the second emitter electrode 2B is disposed on the other side of the finger wiring 3. As indicated by the thick line in FIG. 2, the third emitter electrode 2C is provided on an extension line of the finger wiring 3. The third emitter electrode 2C is provided between a tip of the finger wiring 3 and the gate wiring 5, and connects the first emitter electrode 2A and the second emitter electrode 2B. The first emitter electrode 2A, the second emitter electrode 2B, and the third emitter electrode 2C are one component, and are continuous without being divided except for the finger wiring 3, the finger wiring extension portion 3A, and the gate wiring extension portion 5A in the active portion. Although the emitter electrode 2 (2A, 2B, 2C) seems to be divided into stripes by a large number of horizontal lines illustrating the plurality of gate electrodes 7 in the drawings, actually, the emitter electrode 2 is continuously formed in a layer above the gate electrode 7.

The emitter electrode 2 is electrically insulated from the gate pad 1, the finger wiring 3, the finger wiring extension portion 3A, the gate wiring 5, the gate wiring extension portion 5A, and the gate electrodes 7. That is, the emitter electrode 2 is electrically insulated from the electrodes and the wiring through which the gate signal is transmitted. As an insulating material, for example, an oxide film or the like is used. Although the emitter electrode 2 is drawn as if the emitter electrode 2 is in contact with the finger wiring 3, the finger wiring extension portion 3A, the gate wiring 5, and the gate wiring extension portion 5A in the plan views of FIGS. 1 and 2 for convenience of illustration, the emitter electrode 2 is not actually in contact with these members.

The finger wiring 3 extends in a first direction within a plane of the semiconductor substrate 10, and is disposed so as to traverse the active portion. The first direction in the first preferred embodiment corresponds to the longitudinal direction in FIG. 1. The finger wiring 3 is electrically connected to the gate pad 1. The finger wiring 3 is formed of metal such as aluminum.

The finger wiring extension portion 3A extends from the tip of the finger wiring 3 toward the gate wiring 5 while avoiding the third emitter electrode 2C. The finger wiring extension portion 3A in the first preferred embodiment extends in a second direction from the tip of finger wiring 3 and then further extends in the first direction. The second direction is orthogonal to the first direction. The second direction in the second preferred embodiment corresponds to the lateral direction in FIGS. 1 and 2.

The gate wiring 5 has an annular shape in plan view. The gate wiring 5 is provided so as to surround the emitter electrode 2 provided in the active portion. The gate wiring 5 is electrically connected to the gate pad 1. The gate wiring 5 is made of metal such as aluminum.

The gate wiring extension portion 5A branches off from the gate wiring 5. The gate wiring extension portion 5A extends toward an inside of the annular shape of the gate wiring 5 while avoiding the third emitter electrode 2C. The gate wiring extension portion 5A in the first preferred embodiment branches off from the gate wiring 5 and extends in the first direction.

The plurality of gate electrodes 7 extend in the second direction within the plane of the semiconductor substrate 10, and are provided below the emitter electrode 2 with an insulating layer interposed therebetween. Both ends of the gate electrodes 7 are, for example, electrically connected to the gate wiring 5. The gate electrodes 7 are, for example, formed of polysilicon.

Among the plurality of gate electrodes 7, in plan view, the gate electrode 7 crossing the third emitter electrode 2C is electrically connected to one of the finger wiring extension portion 3A and the gate wiring extension portion 5A in a region inside the annular shape of the gate wiring 5. As illustrated in FIG. 2, in the first preferred embodiment, a part of a gate electrode 7A is in contact with the gate wiring extension portion 5A. A part of each of gate electrodes 7B and 7C is in contact with the finger wiring extension portion 3A. A part of the gate electrode 7D is in contact with the finger wiring extension portion 3A and the finger wiring 3. A part of the gate electrode 7E is in contact with the finger wiring 3. As described above, each of the gate electrodes 7 is in contact with any of the finger wiring 3, the finger wiring extension portion 3A, and the gate wiring extension portion 5A. In other words, the gate electrodes 7 are electrically connected to the gate pad 1 via these wirings.

In such a configuration, the third emitter electrode 2C connects the first emitter electrode 2A and the second emitter electrode 2B, and therefore a potential in the emitter electrode 2 is stabilized.

In a case where the gate electrodes 7 are formed of polysilicon and the finger wiring 3 and the gate wiring 5 are formed of metal, the gate electrodes 7 have a larger resistance value per unit length than the finger wiring 3 and the gate wiring 5. Therefore, a gate signal that transmits through the gate electrodes 7 is delayed more than a gate signal that transmits through the finger wiring 3 or the gate wiring 5. However, each of the gate electrodes 7 in the semiconductor device 101 according to the first preferred embodiment is electrically connected to any of the finger wiring 3, the finger wiring extension portion 3A, and the gate wiring extension portion 5A in a region inside the annular shape of the gate wiring 5. Therefore, the delay of the gate signal is lessened.

To summarize the above, the semiconductor device 101 according to the first preferred embodiment includes the finger wiring 3, the emitter electrode 2, the gate wiring 5, and the plurality of gate electrodes 7. The finger wiring 3 extends in the first direction within the plane of the semiconductor substrate 10. The emitter electrode 2 includes the first emitter electrode 2A and the second emitter electrode 2B arranged so as to sandwich the finger wiring 3. The gate wiring 5 has an annular shape in plan view and is provided so as to surround the emitter electrode 2. The plurality of gate electrodes 7 extend in the second direction within the plane of the semiconductor substrate 10. The emitter electrode 2 includes the third emitter electrode 2C. The third emitter electrode 2C is provided on an extension line of the finger wiring 3. The third emitter electrode 2C is provided between the tip of the finger wiring 3 and the gate wiring 5, and connects the first emitter electrode 2A and the second emitter electrode 2B. The finger wiring 3 includes the finger wiring extension portion 3A. The finger wiring extension portion 3A extends from the tip of the finger wiring 3 toward the gate wiring 5 while avoiding the third emitter electrode 2C. Among the plurality of gate electrodes 7, the gate electrode 7 crossing the third emitter electrode 2C in plan view is electrically connected to the finger wiring extension portion 3A. The emitter electrode 2 is a surface electrode, and may be called differently depending on the type of semiconductor element formed on the semiconductor substrate 10.

In such a semiconductor device 101, the third emitter electrode 2C connects the first emitter electrode 2A and the second emitter electrode 2B although the finger wiring 3 is provided. Therefore, the potential in the emitter electrode 2 is stabilized, and the short circuit tolerance is improved. Furthermore, the gate electrodes 7 are electrically connected to finger wiring extension portion 3A. Therefore, the delay of the gate signal is lessened.

### First Modification of First Preferred Embodiment

FIG. 3 is an enlarged plan view illustrating a configuration of a semiconductor device 101A in a first modification of the first preferred embodiment. The semiconductor device 101A includes the finger wiring extension portion 3A and a gate wiring extension portion 5B. The finger wiring extension portion 3A extends in the second direction from the tip of the finger wiring 3 and then further extends in the first direction, as in the first preferred embodiment. The gate wiring extension portion 5B branches off from the gate wiring 5, extends in the first direction, then extends in the second direction, and further extends in the first direction.

The gate electrodes 7A to 7D crossing the third emitter electrode 2C are electrically connected to one of the finger wiring extension portion 3A and the gate wiring extension portion 5B in a region inside the annular shape of the gate wiring 5. Specifically, a part of each of the gate electrodes 7A and 7B is in contact with the gate wiring extension portion 5B. A part of each of the gate electrodes 7C and 7D is in contact with the finger wiring extension portion 3A.

A part of the gate electrode 7E that does not cross the third emitter electrode 2C is in contact with the finger wiring 3. As described above, each of the gate electrodes 7 is in contact with any of the finger wiring 3, the finger wiring extension portion 3A, and the gate wiring extension portion 5B. Also in the semiconductor device 101A, effects similar to those of the first preferred embodiment can be obtained.

### Second Modification of First Preferred Embodiment

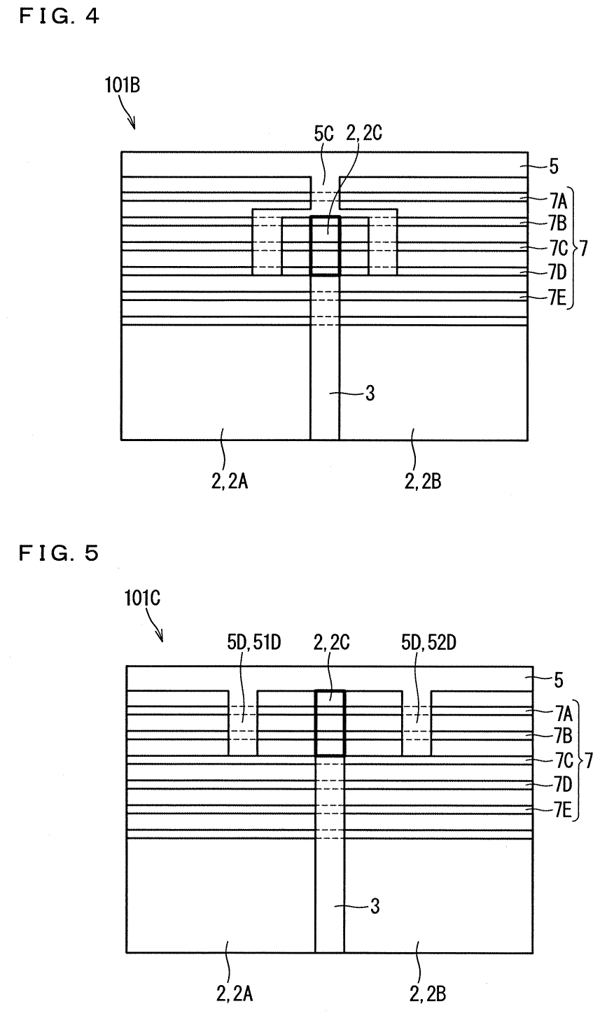

FIG. 4 is an enlarged plan view illustrating a configuration of a semiconductor device 101B in a second modification of the first preferred embodiment. The semiconductor device 101B includes a gate wiring extension portion 5C. The finger wiring extension portion 3A is not provided. The gate wiring extension portion 5C branches off from the gate wiring 5, extends in the first direction, and then bifurcates in the second direction. Tips of the gate wiring extension portion 5C further extend in the first direction.

The gate electrodes 7A to 7D crossing the third emitter electrode 2C are electrically connected to the gate wiring extension portion 5C in a region inside the annular shape of the gate wiring 5. Specifically, a part of each of the gate electrodes 7A to 7D is in contact with the gate wiring extension portion 5C.

A part of the gate electrode 7E that does not cross the third emitter electrode 2C is in contact with the finger wiring 3. As described above, each of the gate electrodes 7 is in contact with any of the finger wiring 3 and the gate wiring extension portion 5C. Also in the semiconductor device 101B, effects similar to those of the first preferred embodiment can be obtained.

### Third Modification of First Preferred Embodiment

FIG. 5 is an enlarged plan view illustrating a configuration of a semiconductor device 101C in a third modification of the first preferred embodiment. The semiconductor device 101C includes a gate wiring extension portion 5D. The finger wiring extension portion 3A is not provided. The gate wiring extension portion 5D includes a plurality of branch wirings 51D and 52D. The plurality of branch wirings 51D and 52D branch off from a plurality of branch points of the gate wiring 5 and extend in the first direction.

The gate electrodes 7A and 7B crossing the third emitter electrode 2C are electrically connected to the gate wiring extension portion 5D in a region inside the annular shape of the gate wiring 5. Specifically, a part of each of the gate electrodes 7A and 7B is in contact with the gate wiring extension portion 5D.

A part of each of the gate electrodes 7C to 7E that do not cross the third emitter electrode 2C is in contact with the finger wiring 3. As described above, each of the gate electrodes 7 is in contact with any of the finger wiring 3 and the gate wiring extension portion 5D. Also in the semiconductor device 101C, effects similar to those of the first preferred embodiment can be obtained.

### Second Preferred Embodiment

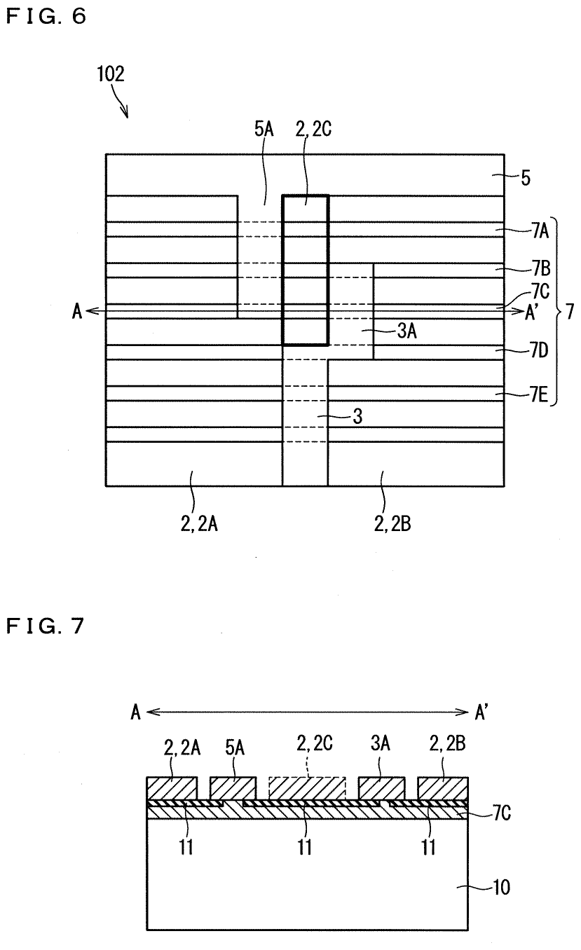

FIG. 6 is a plan view illustrating a configuration of a semiconductor device 102 according to the second preferred embodiment. FIG. 6 illustrates a configuration around a third emitter electrode 2C.

The finger wiring extension portion 3A extends in a second direction from a tip of finger wiring 3 and then further extends in a first direction. A gate wiring extension portion 5A branches off from gate wiring 5 and extends in the first direction.

Gate electrodes 7A to 7D crossing the third emitter electrode 2C are electrically connected to at least one of the finger wiring extension portion 3A and the gate wiring extension portion 5A in a region inside an annular shape of the gate wiring 5. Specifically, a part of the gate electrode 7A is in contact with the gate wiring extension portion 5A. A part of each of the gate electrodes 7B and 7C is in contact with both the gate wiring extension portion 5A and the finger wiring extension portion 3A. A part of the gate electrode 7D is in contact with the finger wiring extension portion 3A.

FIG. 7 is a cross-sectional view illustrating a configuration of the semiconductor device 102. FIG. 7 illustrates a cross-sectional configuration taken along line A-A′ illustrated in FIG. 6. Although the emitter electrode 2 is drawn as if the emitter electrode 2 is in contact with the finger wiring extension portion 3A and the gate wiring extension portion 5A in the plan view of FIG. 6, the emitter electrode 2 is not actually in contact with the finger wiring extension portion 3A and the gate wiring extension portion 5A, as illustrated in FIG. 7. An oxide film 11 is also formed below the wiring, and the emitter electrode 2 is insulated from the finger wiring extension portion 3A and the gate wiring extension portion 5A. The gate electrode 7C is in contact with each of the gate wiring extension portion 5A and the finger wiring extension portion 3A. In such a configuration, delay of a gate signal is further lessened.

### Third Preferred Embodiment

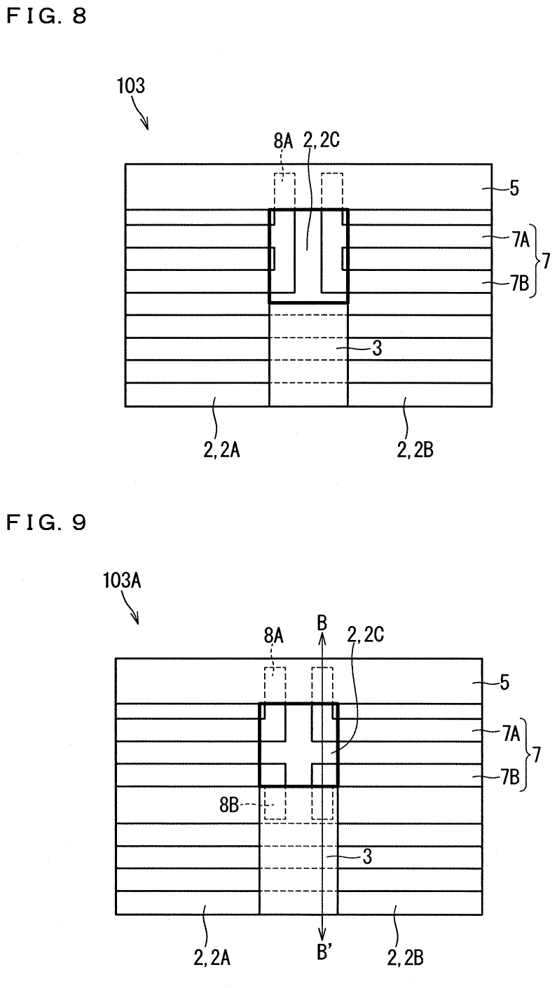

FIG. 8 is a plan view illustrating a configuration of a semiconductor device 103 according to the third preferred embodiment. FIG. 8 illustrates a configuration around a third emitter electrode 2C. A finger wiring extension portion 3A and a gate wiring extension portion 5A are not provided.

Among a plurality of gate electrodes 7, gate electrodes 7A and 7B provided below the third emitter electrode 2C in plan view include gate connection wiring 8A. The gate connection wiring 8A is bent and extends in a first direction below the third emitter electrode 2C. The gate connection wiring 8A is electrically connected to gate wiring 5 in a region outside the third emitter electrode 2C.

The gate electrodes 7A and 7B provided below the third emitter electrode 2C are electrically connected to the gate wiring 5 via the gate connection wiring 8A. Therefore, the delay of the gate signal is lessened. Furthermore, since the finger wiring extension portion 3A and the gate wiring extension portion 5A are not provided, a decrease in an effective region of an active portion that operates as an IGBT is suppressed.

### Modification of Third Preferred Embodiment

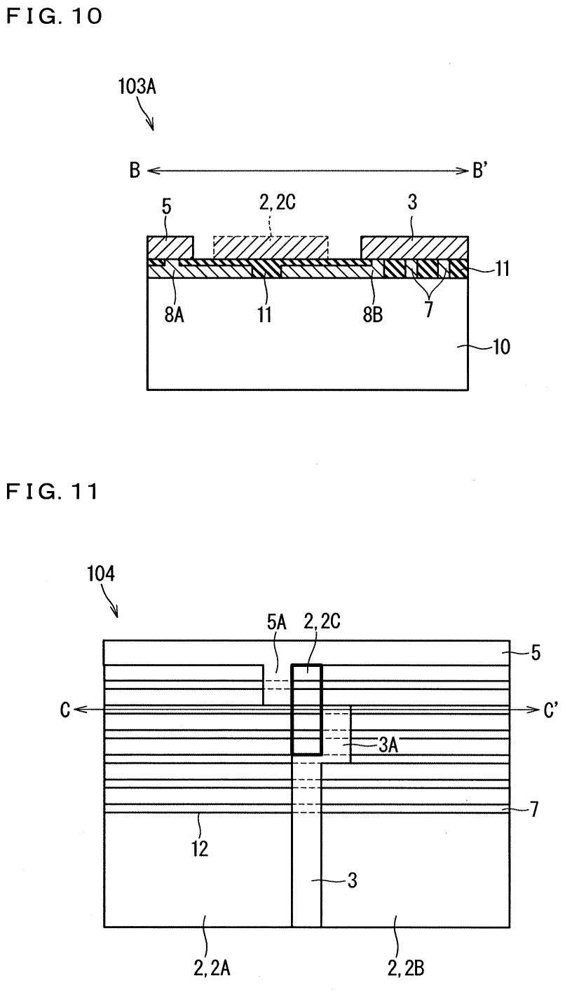

FIG. 9 is a plan view illustrating a configuration of a semiconductor device 103A according to a modification of the third preferred embodiment. FIG. 10 is a cross-sectional view illustrating a configuration of the semiconductor device 103A. FIG. 10 illustrates a cross section taken along line B-B′ illustrated in FIG. 9.

Among the plurality of gate electrodes 7, the gate electrodes 7A and 7B provided below the third emitter electrode 2C in plan view include gate connection wirings 8A and 8B, respectively. The gate connection wiring 8A is bent and extends in a first direction below the third emitter electrode 2C. The gate connection wiring 8A is electrically connected to gate wiring 5 in a region outside the third emitter electrode 2C. The gate connection wiring 8B is bent and extends in the first direction below the third emitter electrode 2C, but is bent in a direction opposite to the gate connection wiring 8A. The gate connection wiring 8B is electrically connected to the finger wiring 3 in a region outside the third emitter electrode 2C.

The gate electrode 7A is electrically connected to the gate wiring 5 via the gate connection wiring 8A. The gate electrode 7B is electrically connected to the finger wiring 3 via the gate connection wiring 8B. Therefore, the delay of the gate signal is lessened. Furthermore, since the finger wiring extension portion 3A and the gate wiring extension portion 5A are not provided, a decrease in an effective region of an active portion that operates as an IGBT is suppressed.

### Fourth Preferred Embodiment

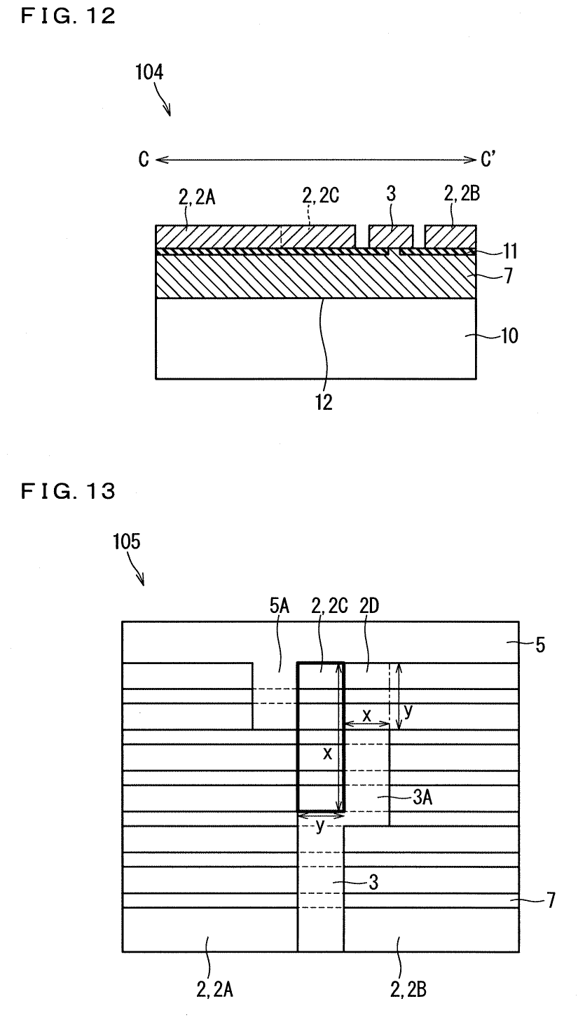

FIG. 11 is a plan view illustrating a configuration of a semiconductor device 104 according to a fourth preferred embodiment. FIG. 12 is a cross-sectional view illustrating a configuration of the semiconductor device 104. FIG. 12 illustrates a cross section taken along line C-C′ illustrated in FIG. 11.

The semiconductor device 104 includes a plurality of trenches 12. The plurality of trenches 12 are provided in a semiconductor substrate 10 and extend in a second direction. A plurality of gate electrodes 7 are provided in the plurality of trenches 12, respectively. Since the gate electrodes 7 are embedded in the trenches 12, a junction field effect transistor (JFET) resistance is reduced.

### Fifth Preferred Embodiment

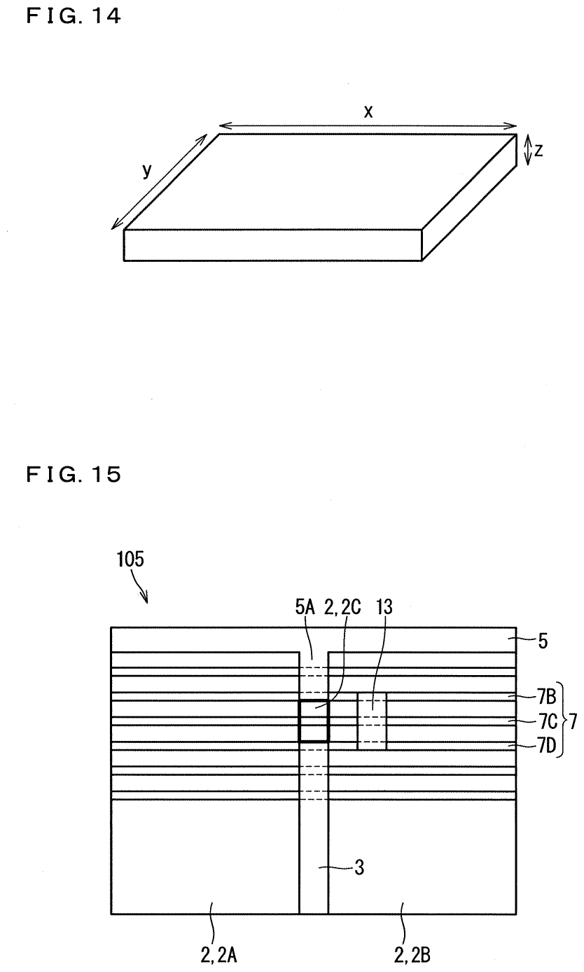

FIG. 13 is a plan view illustrating a configuration of a semiconductor device 105 according to the fifth preferred embodiment. FIG. 13 illustrates a configuration around a third emitter electrode 2C. FIG. 14 is a diagram illustrating a schematic three-dimensional shape of an electrode (AlSi) in an emitter connection region.

A second emitter electrode 2B includes a fourth emitter electrode 2D. The fourth emitter electrode 2D corresponds to a fourth surface electrode. The fourth emitter electrode 2D is provided between a tip of a finger wiring extension portion 3A and gate wiring 5 in a first direction.

A length of the third emitter electrode 2C in the first direction and a width of the fourth emitter electrode 2D in the second direction are denoted by x. A width of the third emitter electrode 2C in the second direction and a length of the fourth emitter electrode 2D in the first direction are denoted by y. A thickness of the chip is denoted by z. Resistivity is denoted by ρ.

When a pitch of gate electrodes 7 is 2.4 μm, it is desirable that the third emitter electrode 2C and the fourth emitter electrode 2D satisfy the following expressions (1) and (2).

$$0.002 x [ ln ( \frac{2 x}{y + z} ) + 0.2235 ( \frac{y + z}{x} ) + 0.5 ] < 5. uH \qquad ( 1 )$$

$$\frac{ρ x}{yz} < 7.5 m Ω \qquad ( 2 )$$

When the pitch of the gate electrodes 7 is 4.0 μm, it is desirable that the third emitter electrode 2C and the fourth emitter electrode 2D satisfy the following expressions (3) and (4).

$$0.002 x [ ln ( \frac{2 x}{y + z} ) + 0.2235 ( \frac{y + z}{x} ) + 0.5 ] < 2.5 uH \qquad ( 3 )$$

$$\frac{ρ x}{yz} < 3. m Ω \qquad ( 4 )$$

The expressions (1) and (3) are expressions concerning inductance in the emitter electrode region. The expressions (2) and (4) are expressions concerning resistance. In a case where both the inductance and the resistance are low, short circuit tolerance is improved.

### Sixth Preferred Embodiment

FIG. 15 is a plan view illustrating a configuration of a semiconductor device 106 according to the sixth preferred embodiment. FIG. 15 illustrates a configuration around a third emitter electrode 2C. The semiconductor device 106 includes island wiring 13.

The island wiring 13 is provided in a region where one of a first emitter electrode 2A and a second emitter electrode 2B is disposed. In FIG. 15, the island wiring 13 is provided in a region where the second emitter electrode 2B is disposed. The island wiring 13 is electrically insulated from the first emitter electrode 2A and the second emitter electrode 2B. On the other hand, the island wiring 13 is electrically connected to a gate electrode 7C crossing the third emitter electrode 2C and gate electrodes 7B and 7D other than the gate electrode 7C crossing the third emitter electrode 2C among a plurality of gate electrodes 7.

A part of the gate electrode 7B is in contact with a gate wiring extension portion 5A and the island wiring 13. A part of the gate electrode 7C is in contact with the island wiring 13. A part of the gate electrode 7D is in contact with finger wiring 3 and the island wiring 13. That is, the gate electrode 7C crossing the third emitter electrode 2C is electrically connected to the finger wiring 3 and the gate wiring extension portion 5A via the island wiring 13. Also in such a configuration, effects similar to those of the first preferred embodiment can be obtained.

Even in a case where the gate electrode 7C is electrically connected to any one of the finger wiring 3 and the gate wiring extension portion 5A via the island wiring 13, the same effects as described above can be obtained. Furthermore, in a case where the finger wiring extension portion 3A is provided (not illustrated), the island wiring 13 may be electrically connected to the finger wiring extension portion 3A. In this case, the gate electrode 7C crossing the third emitter electrode 2C is electrically connected to the finger wiring extension portion 3A via the island wiring 13. That is, the gate electrode 7C need just be electrically connected to any of the finger wiring 3, the finger wiring extension portion 3A, and the gate wiring extension portion 5A via the island wiring 13.

### Seventh Preferred Embodiment

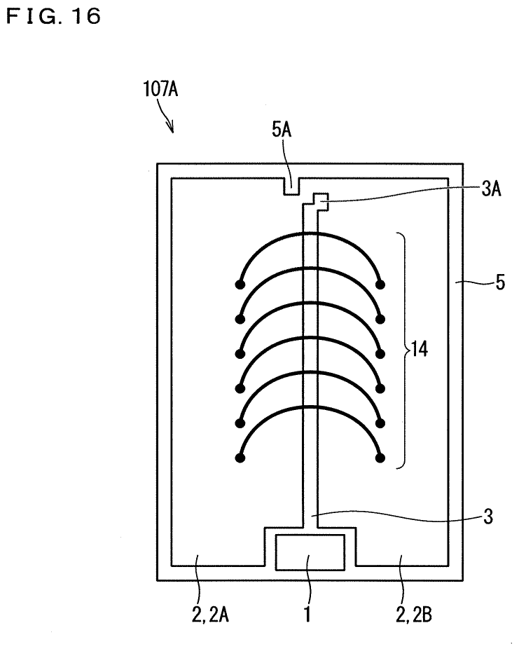

FIG. 16 is a diagram illustrating a configuration of a semiconductor device 107A according to the seventh preferred embodiment. As illustrated in FIG. 16, the semiconductor device 107A includes a wire 14 that connects a first emitter electrode 2A and a second emitter electrode 2B. A potential of the first emitter electrode 2A and a potential of the second emitter electrode 2B are stabilized, and short circuit tolerance is further improved.

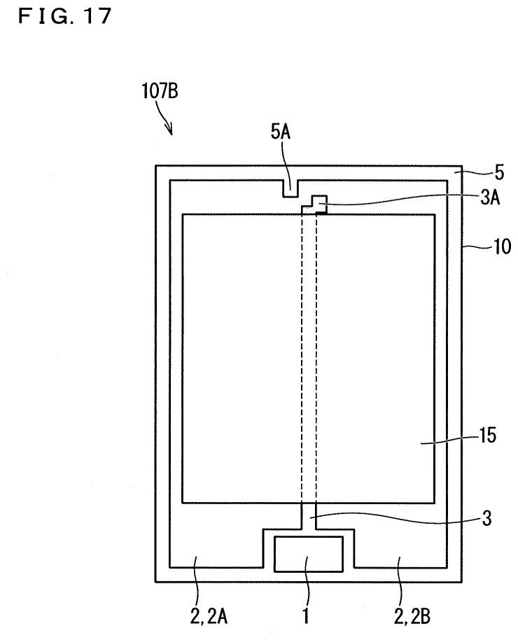

FIG. 17 is a diagram illustrating a configuration of a semiconductor device 107B according to the seventh preferred embodiment. As illustrated in FIG. 17, the semiconductor device 107B includes a metal plate 15 that connects the first emitter electrode 2A and the second emitter electrode 2B. The metal plate 15 is directly bonded to the first emitter electrode 2A and the second emitter electrode 2B by, for example, direct lead bonding (DLB). A potential of the first emitter electrode 2A and a potential of the second emitter electrode 2B are stabilized, and short circuit tolerance is further improved. Heat dissipation during switching operation is also improved.

### Eighth Preferred Embodiment

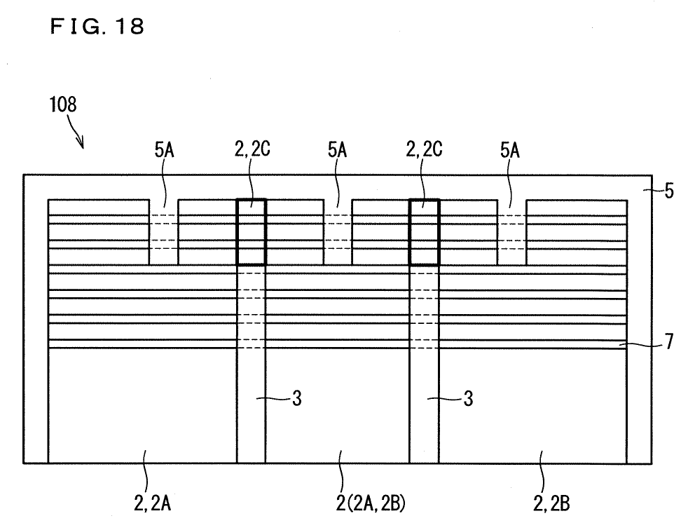

FIG. 18 is a diagram illustrating a configuration of a semiconductor device 108 according to the eighth preferred embodiment. The semiconductor device 108 includes a plurality of finger wirings 3 and a plurality of gate wiring extension portions 5A. The semiconductor device 108 may include a plurality of finger wiring extension portions 3A (not illustrated). That is, the number of finger wirings 3, the number of finger wiring extension portions 3A, and the number of gate wiring extension portions 5A may be two or more. In FIG. 18, when the left finger wiring 3 is used as a reference, the electrode on the left of the finger wiring 3 is a first emitter electrode 2A, and the electrode on the right of the finger wiring 3 is a second emitter electrode 2B. When the right finger wiring 3 is used as a reference, the electrode on the left of the finger wiring 3 is the first emitter electrode 2A, and the electrode on the right of the finger wiring 3 is the second emitter electrode 2B. The electrode illustrated in the center of FIG. 18 may be defined as the first emitter electrode 2A or may be defined as the second emitter electrode 2B depending on which finger wiring 3 is used as a reference.

In a case where the emitter electrode 2 is divided into three or more regions, delay of a gate signal is lessened and short circuit tolerance is improved by providing two or more finger wirings 3, two or more finger wiring extension portions 3A, and two or more gate wiring extension portions 5A.

The preferred embodiments of the present disclosure can be freely combined and changed or omitted as appropriate.

Various aspects of the present disclosure will be collectively described below as an appendix.

### APPENDIX 1

A semiconductor device comprising:
finger wiring extending in a first direction within a plane of a semiconductor substrate;
a surface electrode including a first surface electrode and a second surface electrode arranged so as to sandwich the finger wiring;
gate wiring having an annular shape in plan view and provided so as to surround the surface electrode; and
a plurality of gate electrodes extending in a second direction within the plane of the semiconductor substrate,
wherein the surface electrode includes a third surface electrode provided on an extension line of the finger wiring and connecting the first surface electrode and the second surface electrode between a tip of the finger wiring and the gate wiring,
the finger wiring includes a finger wiring extension portion extending from the tip of the finger wiring toward the gate wiring while avoiding the third surface electrode, and
among the plurality of gate electrodes, a gate electrode crossing the third surface electrode in plan view is electrically connected to the finger wiring extension portion.

### APPENDIX 2

The semiconductor device according to Appendix 1, wherein the finger wiring extension portion extends in the second direction from the tip of the finger wiring and then further extends in the first direction.

### APPENDIX 3

The semiconductor device according to Appendix 1 or 2, wherein
the gate wiring includes a gate wiring extension portion branching off from the gate wiring and extending to an inside of the annular shape of the gate wiring while avoiding the third surface electrode, and
the gate electrode crossing the third surface electrode is electrically connected to at least one of the gate wiring extension portion and the finger wiring extension portion.

### APPENDIX 4

The semiconductor device according to Appendix 3, wherein the gate wiring extension portion branches off from the gate wiring, extends in the first direction, then extends in the second direction, and further extends in the first direction.

### APPENDIX 5

A semiconductor device comprising:
finger wiring extending in a first direction within a plane of a semiconductor substrate;
a surface electrode including a first surface electrode and a second surface electrode arranged so as to sandwich the finger wiring;
gate wiring having an annular shape in plan view and provided so as to surround the surface electrode; and
a plurality of gate electrodes extending in a second direction within the plane of the semiconductor substrate,
wherein the surface electrode includes a third surface electrode provided on an extension line of the finger wiring and connecting the first surface electrode and the second surface electrode between a tip of the finger wiring and the gate wiring,
the gate wiring includes a gate wiring extension portion branching off from the gate wiring and extending to an inside of the annular shape of the gate wiring while avoiding the third surface electrode, and
among the plurality of gate electrodes, a gate electrode crossing the third surface electrode in plan view is electrically connected to the gate wiring extension portion.

### APPENDIX 6

The semiconductor device according to Appendix 5, wherein
the gate wiring extension portion branches off from the gate wiring, extends in the first direction, and then bifurcates in the second direction, and
a tip of the gate wiring extension portion extends in the first direction.

### APPENDIX 7

The semiconductor device according to Appendix 5 or 6, wherein the gate wiring extension portion includes a plurality of branch wirings branching off from a plurality of branch points of the gate wiring and extending in the first direction.

### APPENDIX 8

The semiconductor device according to Appendix 3, wherein the gate electrode crossing the third surface electrode is electrically connected to both the gate wiring extension portion and the finger wiring extension portion.

### APPENDIX 9

A semiconductor device comprising:
finger wiring extending in a first direction within a plane of a semiconductor substrate;
a surface electrode including a first surface electrode and a second surface electrode arranged so as to sandwich the finger wiring;
gate wiring having an annular shape in plan view and provided so as to surround the surface electrode; and
a plurality of gate electrodes extending in a second direction within the plane of the semiconductor substrate,
wherein the surface electrode includes a third surface electrode provided on an extension line of the finger wiring and connecting the first surface electrode and the second surface electrode between a tip of the finger wiring and the gate wiring,
among the plurality of gate electrodes, a gate electrode provided below the third surface electrode in plan view includes gate connection wiring, and
the gate connection wiring is bent and extends in the first direction below the third surface electrode and is electrically connected to the gate wiring in a region outside the third surface electrode.

### APPENDIX 10

The semiconductor device according to Appendix 9, wherein the gate connection wiring is bent and extends in the first direction below the third surface electrode and is electrically connected to the finger wiring in a region outside the third surface electrode.

### APPENDIX 11

The semiconductor device according to any one of Appendixes 1 to 10, wherein the plurality of gate electrodes are provided in a plurality of trenches provided in the semiconductor substrate and extending in the second direction.

### APPENDIX 12

The semiconductor device according to Appendix 1, wherein
the second surface electrode includes a fourth surface electrode provided between a tip of the finger wiring extension portion and the gate wiring in the first direction, and
when a length of the third surface electrode in the first direction and a width of the fourth surface electrode in the second direction are denoted by x, a width of the third surface electrode in the second direction and a length of the fourth surface electrode in the first direction are denoted by y, and a thickness of a chip is denoted by z, the third surface electrode and the fourth surface electrode satisfy the following two expressions.

$$\begin{matrix}0.002 x [ ln ( \frac{2 x}{y + z} ) + 0.2235 ( \frac{y + z}{x} ) + 0.5 ] < 5. uH \\ \frac{ρ x}{yz} < 7.5 m Ω\end{matrix}$$

### APPENDIX 13

The semiconductor device according to Appendix 1, wherein
the first surface electrode includes a fourth surface electrode provided between a tip of the finger wiring extension portion and the gate wiring in the first direction, and
when a length of the third surface electrode in the first direction and a width of the fourth surface electrode in the second direction are denoted by x, a width of the third surface electrode in the second direction and a length of the fourth surface electrode in the first direction are denoted by y, and a thickness of a chip is denoted by z, the third surface electrode and the fourth surface electrode satisfy the following two expressions.

$$\begin{matrix}0.002 x [ ln ( \frac{2 x}{y + z} ) + 0.2235 ( \frac{y + z}{x} ) + 0.5 ] < 2.5 uH \\ \frac{ρ x}{yz} < 3. m Ω\end{matrix}$$

### APPENDIX 14

The semiconductor device according to any one of Appendixes 3 to 8, further comprising island wiring provided in a region where one of the first surface electrode and the second surface electrode is disposed and insulated from the first surface electrode and the second surface electrode,
wherein the island wiring is electrically connected to the gate electrode crossing the third surface electrode and a gate electrode other than the gate electrode crossing the third surface electrode among the plurality of gate electrodes, and
the gate electrode crossing the third surface electrode is electrically connected to any of the finger wiring and the gate wiring extension portion via the island wiring.

### APPENDIX 15

The semiconductor device according to any one of Appendixes 1 to 14, further comprising a wire that connects the first surface electrode and the second surface electrode.

### APPENDIX 16

The semiconductor device according to any one of Appendixes 1 to 15, further comprising a metal plate that connects the first surface electrode and the second surface electrode.

### APPENDIX 17

The semiconductor device according to Appendix 3 or 4, wherein the number of finger wirings, the number of finger wiring extension portions, and the number of gate wiring extension portions are two or more.

While the disclosure has been shown and described in detail, the foregoing description is in all aspects illustrative and not restrictive. It is therefore understood that numerous modifications and variations can be devised.

What is claimed is:

1. A semiconductor device comprising:
finger wiring extending in a first direction within a plane of a semiconductor substrate;
a surface electrode including a first surface electrode and a second surface electrode arranged so as to sandwich the finger wiring;
gate wiring having an annular shape in plan view and provided so as to surround the surface electrode; and
a plurality of gate electrodes extending in a second direction within the plane of the semiconductor substrate,
wherein the surface electrode includes a third surface electrode provided on an extension line of the finger wiring and connecting the first surface electrode and the second surface electrode between a tip of the finger wiring and the gate wiring,
the finger wiring includes a finger wiring extension portion extending from the tip of the finger wiring toward the gate wiring while avoiding the third surface electrode, and
among the plurality of gate electrodes, a gate electrode crossing the third surface electrode in plan view is electrically connected to the finger wiring extension portion.

2. The semiconductor device according to claim 1, wherein the finger wiring extension portion extends in the second direction from the tip of the finger wiring and then further extends in the first direction.

3. The semiconductor device according to claim 1, wherein
the gate wiring includes a gate wiring extension portion branching off from the gate wiring and extending to an inside of the annular shape of the gate wiring while avoiding the third surface electrode, and
the gate electrode crossing the third surface electrode is electrically connected to at least one of the gate wiring extension portion and the finger wiring extension portion.

4. The semiconductor device according to claim 3, wherein the gate wiring extension portion branches off from the gate wiring, extends in the first direction, then extends in the second direction, and further extends in the first direction.

5. A semiconductor device comprising:
finger wiring extending in a first direction within a plane of a semiconductor substrate;
a surface electrode including a first surface electrode and a second surface electrode arranged so as to sandwich the finger wiring;
gate wiring having an annular shape in plan view and provided so as to surround the surface electrode; and
a plurality of gate electrodes extending in a second direction within the plane of the semiconductor substrate,
wherein the surface electrode includes a third surface electrode provided on an extension line of the finger wiring and connecting the first surface electrode and the second surface electrode between a tip of the finger wiring and the gate wiring,
the gate wiring includes a gate wiring extension portion branching off from the gate wiring and extending to an inside of the annular shape of the gate wiring while avoiding the third surface electrode, and
among the plurality of gate electrodes, a gate electrode crossing the third surface electrode in plan view is electrically connected to the gate wiring extension portion.

6. The semiconductor device according to claim 5, wherein
the gate wiring extension portion branches off from the gate wiring, extends in the first direction, and then bifurcates in the second direction, and
a tip of the gate wiring extension portion extends in the first direction.

7. The semiconductor device according to claim 5, wherein the gate wiring extension portion includes a plurality of branch wirings branching off from a plurality of branch points of the gate wiring and extending in the first direction.

8. The semiconductor device according to claim 3, wherein the gate electrode crossing the third surface electrode is electrically connected to both the gate wiring extension portion and the finger wiring extension portion.

9. A semiconductor device comprising:
finger wiring extending in a first direction within a plane of a semiconductor substrate;
a surface electrode including a first surface electrode and a second surface electrode arranged so as to sandwich the finger wiring;
gate wiring having an annular shape in plan view and provided so as to surround the surface electrode; and
a plurality of gate electrodes extending in a second direction within the plane of the semiconductor substrate,
wherein the surface electrode includes a third surface electrode provided on an extension line of the finger wiring and connecting the first surface electrode and the second surface electrode between a tip of the finger wiring and the gate wiring,
among the plurality of gate electrodes, a gate electrode provided below the third surface electrode in plan view includes gate connection wiring, and
the gate connection wiring is bent and extends in the first direction below the third surface electrode and is electrically connected to the gate wiring in a region outside the third surface electrode.

10. The semiconductor device according to claim 9, wherein the gate connection wiring is bent and extends in the first direction below the third surface electrode and is electrically connected to the finger wiring in a region outside the third surface electrode.

11. The semiconductor device according to claim 1, wherein the plurality of gate electrodes are provided in a plurality of trenches provided in the semiconductor substrate and extending in the second direction.

12. The semiconductor device according to claim 1, wherein
the second surface electrode includes a fourth surface electrode provided between a tip of the finger wiring extension portion and the gate wiring in the first direction, and
when a length of the third surface electrode in the first direction and a width of the fourth surface electrode in the second direction are denoted by x, a width of the third surface electrode in the second direction and a length of the fourth surface electrode in the first direction are denoted by y, and a thickness of a chip is denoted by z, the third surface electrode and the fourth surface electrode satisfy
$$\begin{matrix}0.002 x [ ln ( \frac{2 x}{y + z} ) + 0.2235 ( \frac{y + z}{x} ) + 0.5 ] < 5. uH \\ \frac{ρ x}{yz} < 7.5 m Ω\end{matrix} .$$

13. The semiconductor device according to claim 1, wherein
the first surface electrode includes a fourth surface electrode provided between a tip of the finger wiring extension portion and the gate wiring in the first direction, and
when a length of the third surface electrode in the first direction and a width of the fourth surface electrode in the second direction are denoted by x, a width of the third surface electrode in the second direction and a length of the fourth surface electrode in the first direction are denoted by y, and a thickness of a chip is denoted by z, the third surface electrode and the fourth surface electrode satisfy
$$\begin{matrix}0.002 x [ ln ( \frac{2 x}{y + z} ) + 0.2235 ( \frac{y + z}{x} ) + 0.5 ] < 2.5 uH \\ \frac{ρ x}{yz} < 3. m Ω\end{matrix} .$$

14. The semiconductor device according to claim 3, further comprising island wiring provided in a region where one of the first surface electrode and the second surface electrode is disposed and insulated from the first surface electrode and the second surface electrode,
wherein the island wiring is electrically connected to the gate electrode crossing the third surface electrode and a gate electrode other than the gate electrode crossing the third surface electrode among the plurality of gate electrodes, and
the gate electrode crossing the third surface electrode is electrically connected to any of the finger wiring and the gate wiring extension portion via the island wiring.

15. The semiconductor device according to claim 1, further comprising a wire that connects the first surface electrode and the second surface electrode.

16. The semiconductor device according to claim 1, further comprising a metal plate that connects the first surface electrode and the second surface electrode.

17. The semiconductor device according to claim 3, wherein the number of finger wirings, the number of finger wiring extension portions, and the number of gate wiring extension portions are two or more.
